(19) United States
(12) Patent Application Publication
(10) Pub. No.: US 2009/0087550 A1
(43) Pub. Date: Apr. 2, 2009

(54) SEQUENTIAL FLOW DEPOSITION OF A TUNGSTEN SILICIDE GATE ELECTRODE FILM

(75) Inventors: Gerrit J. Leusink, Saltpoint, NY (US); Emmanual P. Guidotti, Barberaz (FR)

Correspondence Address: TOKYO ELECTRON U.S. HOLDINGS, INC., 4350 W. CHANDLER BLVD., SUITE 10, CHANDLER, AZ, 85226, US

(73) Assignee: TOKYO ELECTRON LIMITED, Tokyo (JP)

(21) Appl. No.: 11/863,080

(22) Filed: Sep. 27, 2007

(51) Int. Cl. C23C 16/06

(52) U.S. Cl. 427/126.1

(57) ABSTRACT

A method is provided for forming WSiₓ gate electrode films with tunable Si/W atomic ratios, low oxygen and carbon film impurities, and work functions suitable for advanced semiconductor devices. The method includes providing a substrate containing a high-k film in a process chamber, maintaining the substrate at a temperature between 450° C. and 550° C., and performing a plurality of deposition cycles to form a WSiₓ gate electrode film on the high-k film. According to embodiments of the invention, each deposition cycle includes exposing the substrate to a first process gas containing W(CO)₆ vapor to thermally deposit a W metal film with a thickness between 0.1 nm and less than 2 nm, and exposing the W metal film to a second process gas containing SiH₄ to form a WSiₓ film having a Si/W atomic ratio controlled by self-limited Si incorporation into the W metal film. The method further includes patterning the WSiₓ gate electrode film and high-k film to form a gate stack.

### CROSS-REFERENCE TO RELATED APPLICATION

This application is related to co-pending U.S. patent application Ser. No. 10/673,910, entitled METHOD FOR DEPOSITING METAL LAYERS USING SEQUENTIAL FLOW DEPOSITION and filed on Sep. 30, 2003, the entire content of which is incorporated herein by reference. The related application is not commonly-owned.

### FIELD OF INVENTION

The field of the invention relates generally to the field of semiconductor device manufacturing and, more specifically, to formation of a tungsten silicide (WSiₓ) gate electrode film with tunable tungsten to silicon ratios, low carbon and oxygen film impurities, and work functions that are suitable for advanced semiconductor devices.

### BACKGROUND OF THE INVENTION

In semiconductor devices, the relatively poor electric conductivity of polysilicon used for gate electrodes in gate stacks is a major limitation on the device performance. The need for replacing polysilicon with a low resistivity material with high stability has resulted in the use of metal and metal-containing gate electrodes. Furthermore, the use of metal or metal-containing gate electrodes is intended to solve the polysilicon depletion effect, an artifact of ultra-thin gate dielectrics and high-channel doping that creates a change in the depletion layer near the polysilicon/gate dielectric interface, which in turn creates a voltage drop across the polysilicon gate electrode. The result is a reduction in channel current and degradation in device performance. When using metal and metal-containing gate electrodes, there is no polysilicon depletion problem. Furthermore, the expectation is that metal and metal-containing gate electrodes are more compatible with gate dielectric materials containing high-dielectric-constant (high-k) materials, allowing further scalability to smaller linewidths. A goal in the use of high-k materials is to continue reduction of the effective oxide thickness (EOT) of the gate dielectric material while keeping gate leakage low and under control.

The work function of a metal or metal-containing material is a key consideration when selecting new gate electrode materials, since the work function is an important material parameter that affects device threshold voltage (Vₜ) of a semiconductor device. One difficulty with finding a metal or metal-containing material with the right work function is that the effective work function of a gate stack changes with processing steps required to manufacture the semiconductor device, since any thermal treatment, oxide deposition, charges and electric dipoles can shift the work function. It is hard to predict what material will have the right work function at the end of the required processing steps.

Promising metal-containing gate electrode materials to replace polysilicon include refractory metal-silicides such as tungsten disilicide (WSi₂). For example, WSi₂ has potential as a mid-gap gate electrode material with a work function below that of W metal (˜4.5 eV) and silicon-rich WSi₂ (WSiₓ, where x>2) has potential as a n-type gate electrode material. Furthermore, WSi₂ is an attractive material for integrating with W metal as p-type gate electrode. Tungsten silicide (WSiₓ) is an electrically conductive material that can be deposited in semiconductor manufacturing by low-pressure chemical vapor deposition (LPCVD), e.g., using silane (SiH₄) or dichlorosilane (SiCl₂H₂) and tungsten hexafluoride (WF₆). LPCVD presents several advantages over physical vapor deposition (PVD) techniques, such as improved step coverage, good control of film stoichiometry, and the possibility of selective deposition. However, the use of halogen-containing gases such as SiCl₂H₂ and WF₆ results in detrimental halogen incorporation into the WSiₓ films.

Use of WSiₓ gate electrode materials offers a fairly easy integration path since deposition of these materials on substrates can utilize process gases and techniques commonly found in semiconductor manufacturing environments. Requirements for integration of WSiₓ gate electrode materials in semiconductor devices include excellent WSiₓ film thickness and WSiₓ film composition uniformity across large substrates such as 300 mm substrates, no halogen film impurities, low oxygen (O) and carbon (C) film impurities, and tunable Si/W atomic ratios for work function control.

### SUMMARY OF THE INVENTION

A method is provided for forming WSiₓ gate electrode films with tunable Si/W atomic ratios for work function control that is suitable for gate stacks in advanced semiconductor devices. According to embodiments of the invention, the silicon/tungsten (Si/W) atomic ratios may be varied between greater than 0.76 and 3.5-4. Furthermore, low O and C film impurities enable integration of the WSiₓ gate electrode films into gate stacks while preventing or causing only small increases in the EOT of the gate stacks during processing.

According to one embodiment of the invention, the method includes providing a substrate containing a high-k film in a process chamber, maintaining the substrate at a temperature between 450° C. and 550° C., and performing a plurality of deposition cycles to form a WSiₓ gate electrode film on the high-k film. Each deposition cycle includes exposing the substrate to a first process gas containing W(CO)₆ vapor to thermally deposit a W metal film with a thickness between 0.1 nm and less than 2 nm, and exposing the W metal film to a second process gas comprising SiH₄ to form a WSiₓ film having a Si/W atomic ratio controlled by self-limited Si incorporation into the W metal film. The method further includes patterning the WSiₓ gate electrode film and high-k film to form a gate stack for a semiconductor device.

### BRIEF DESCRIPTION OF THE DRAWINGS

The present invention is illustrated by way of example and not as a limitation in the figures of the accompanying drawings.

FIGS. 1A-1E schematically show a method for forming a gate stack according to an embodiment of the invention;

FIG. 2 schematically shows gas flows during sequential flow deposition of a WSiₓ gate electrode film according to an embodiment of the invention;

FIG. 3 is a process flow diagram for forming a gate stack according to an embodiment of the invention; and

FIG. 4 depicts a schematic view of a processing system for forming a WSiₓ gate electrode film according to an embodiment of the invention.

### DETAILED DESCRIPTION OF SEVERAL EMBODIMENTS

Formation of a WSiₓ gate electrode film by sequential flow deposition is disclosed in various embodiments. Sequential flow deposition provides excellent WSiₓ film thickness and composition uniformity across large substrates using in semiconductor manufacturing, no halogen impurities since the precursors include W(CO)₆ and SiH₄, low O and C impurities, and tunable Si/W atomic ratios that may be varied between greater than 0.76 and 3.5-4, thereby providing for flexible work function control of the WSiₓ gate electrode film and a semiconductor device containing the WSiₓ gate electrode film. In general, increasing the Si/W atomic ratio (higher Si content) results in lowering of the work function for a WSiₓ gate electrode film. The work function of the WSiₓ gate electrode film can be varied between about 0 eV and about 0.3 eV below the workfunction of W metal (˜4.5 eV).

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

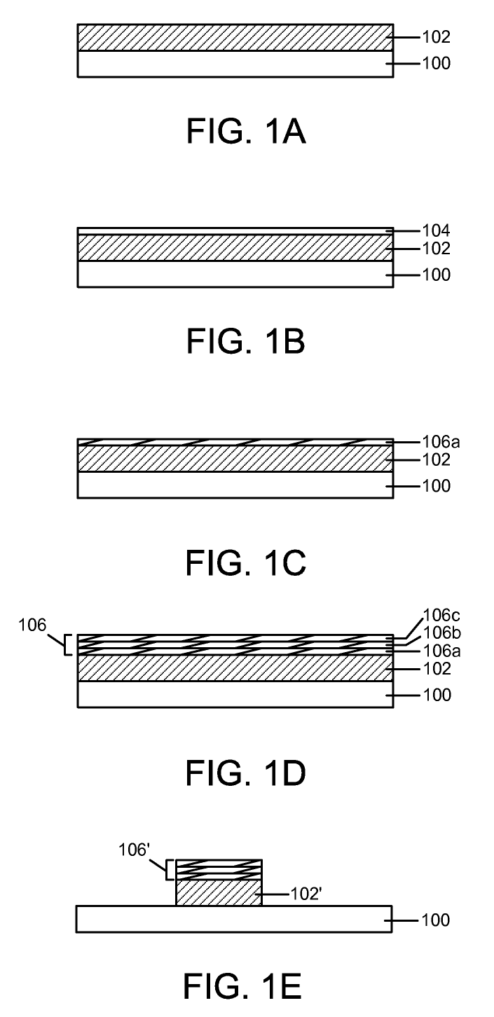

FIGS. 1A-1E schematically show a method for forming a gate stack according to an embodiment of the invention. FIG. 1A schematically shows a cross-sectional view of a substrate 100 containing a high-k film 102. The substrate 100 can, for example, be a 200 mm Si wafer, a 300 mm Si wafer, or an even larger Si wafer. In addition to Si wafers, the substrate 100 can, for example, include a LCD substrate, a glass substrate, or a compound semiconductor substrate. The high-k film 102 formed on the substrate 100 can include metal oxides, metal oxynitrides, and their silicates, for example Ta₂O₅, TiO₂, Al₂O₃, Y₂O₃, HfOₓN_{y}, HfSiOₓN_{y}, HfSiOₓ, HfO₂, ZrO₂, ZrSiOₓ, ZrOₓN_{y}, ZrSiOₓN_{y}, TaSiOₓ, SrOₓ, SrSiOₓ, LaOₓ, LaSiOₓ, YOₓ, YSiOₓ, or BaO, or combinations of two or more thereof. However, embodiments of the invention are not limited to these high-k materials and other high-k materials suitable for advanced gate stacks may be used. Although not shown in FIG. 1A, an interface layer containing SiO₂, SiON, or SiN, or a combination thereof, may be present between the high-k film 102 and the substrate 100.

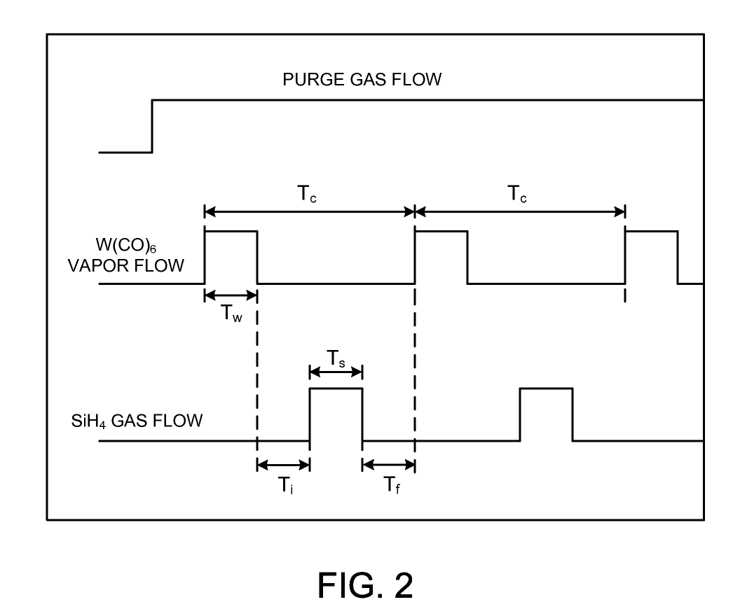

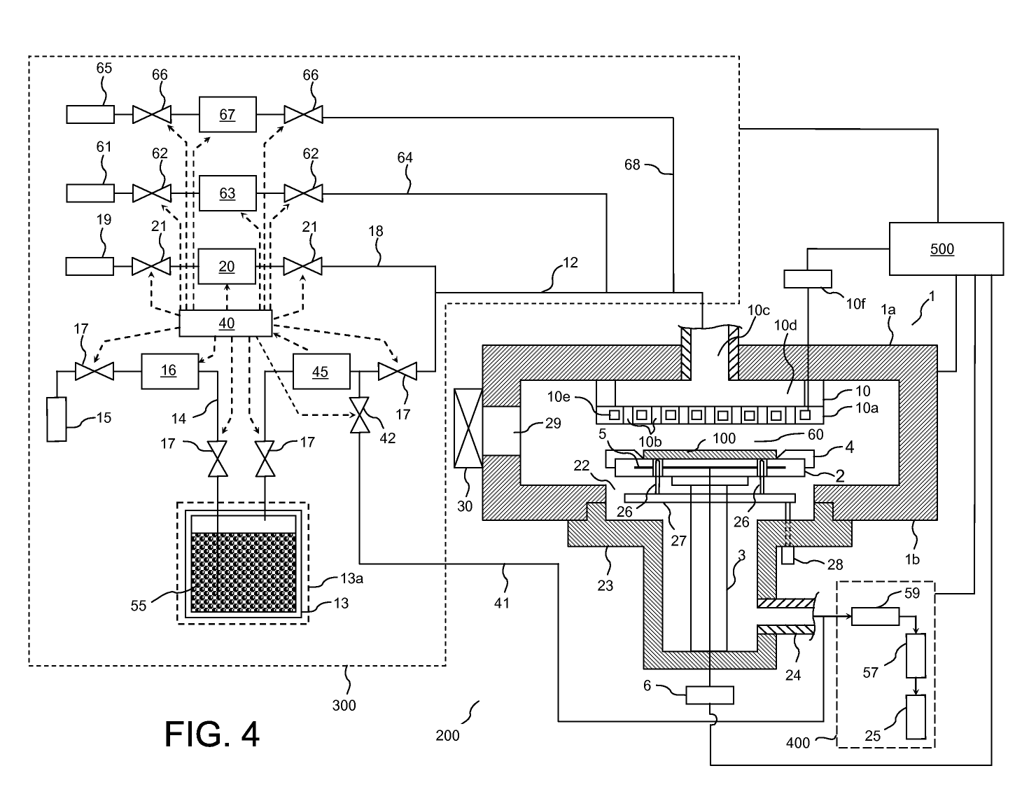

FIG. 2 schematically shows gas flows during sequential flow deposition of a WSiₓ gate electrode film in a process chamber of a processing system according to an embodiment of the invention and FIG. 4 shows a simplified block-diagram of a processing system that may be utilized for performing the sequential flow deposition.

According to the embodiment of the invention illustrated in FIG. 2, a purge gas is introduced into the process chamber and is continuously flowed during the sequential flow deposition process. The flow rate of the purge gas can be constant or the flow rate can be varied during the sequential flow deposition. The purge gas can be selected to efficiently remove excess reactants (e.g., W(CO)₆ vapor and SiH₄ gas) and reaction by-products such as CO and H₂ from the process chamber. The purge gas can, for example, contain in inert gas such as Ar, He, Kr, Xe, and N₂. During the sequential flow deposition, a first process gas containing W(CO)₆ vapor and a second process gas containing SiH₄ gas are sequentially and alternately flowed into the process chamber and exposed to the substrate 100. The first process gas contains W(CO)₆ vapor and can further contain a carrier gas, a dilution gas, or both. The carrier and dilution gases can, for example, contain inert gases such as Ar, He, Kr, Xe, and N₂. During the deposition process, gases are continuously being exhausted from the process chamber using a vacuum pumping system.

Continuing with FIG. 2, after the purge gas flow is created in the process chamber, the first process gas containing the W(CO)₆ vapor is flowed into the process chamber and exposed to the substrate 100 for a predetermined time period T_{w}. The length of time period T_{w} is selected to deposit a W metal film 104 with a desired thickness. The length of time period T_{w} can depend on dilution of the W(CO)₆ vapor with an inert gas, gas pressure in the process chamber, and gas flow characteristics of the process chamber. In one example, a gas flow of the W(CO)₆ vapor in the first process gas can be between 1 sccm and 50 sccm. FIG. 1B shows a W metal film 104 deposited on the high-k film 102. According to embodiments of the invention, a thickness of the W metal film 104 deposited during time period T_{w} can be between 0.1 nm (nm=10⁻⁹ m) and less than 2 nm (e.g., 1.9 nm). At the end of time period T_{w}, the flow of the first process gas containing the W(CO)₆ vapor is interrupted, and the process chamber is purged for a time period Tᵢ by the purge gas and optionally a dilution gas.

According to embodiments of the invention, a reducing gas may be omitted when thermally depositing the W metal film 104 from W(CO)₆ vapor, because the W atom in the W(CO)₆ vapor is already zero-valent. Thermal decomposition of W(CO)₆ vapor and subsequent W metal deposition is thought to proceed predominantly by CO elimination and desorption of CO by-products from the substrate. Unlike atomic layer deposition (ALD) methods for forming W metal films, embodiments of the invention utilize a substrate temperature between 450° C. and 550° C. during deposition of the W metal film 104, which is above the thermal decomposition temperature (˜200° C.) of W(CO)₆.

Still referring to FIG. 2, at the end of time period Tᵢ, a second process gas containing SiH₄ gas is exposed to the W metal film 104 in the process chamber for a predetermined time period Tₛ to form a WSiₓ film 106a having a Si/W atomic ratio (i.e., x in WSiₓ) that is controlled by self-limited Si incorporation into the W metal film 104. The SiH₄ exposure converts at least an exposed surface portion of the W metal film 104 to a WSiₓ film in a self-limiting process. The length of time period Tₛ can depend on dilution of the SiH₄ gas with an inert gas, gas pressure in the process chamber, and flow characteristics of the process chamber. These parameters are selected to provide a SiH₄ gas saturation exposure that saturates the reaction of the SiH₄ gas with the W metal film 104 in a self-limiting process to form the WSiₓ film 106a. In one example, the second process gas can consist of undiluted SiH₄ gas. Exemplary SiH₄ gas flows are between 50 sccm and 500 sccm, or between 100 sccm and 200 sccm.

The basic mechanism of the self-limiting reaction of the SiH₄ gas with the W metal film 104 is diffusion of a Si species (e.g., SiHₓ) through an existing WSiₓ surface portion of the W metal film 104 and further reaction of the Si species with an unreacted portion of the W metal film 104. In a self-limiting process, the rate of Si incorporation decreases as the thicknesses of the W metal film 104 and the WSiₓ surface portion increase. This is likely due to hindered diffusion of the Si species through the existing WSiₓ film to any unreacted portion of the W metal film 104.

At the end of time period Tₛ, the flow of the second process gas containing SiH₄ gas is interrupted, and the process chamber is purged for a time period T_{f} by a purge gas and optionally a dilution gas. Time periods Tᵢ and T_{f} can be equal in length, or they can vary in length.

In the sequential flow deposition process schematically shown in FIG. 2, a deposition cycle T_{c} consists of time periods T_{w}, Tᵢ, Tₛ, and T_{f}. During time period T_{w}, the thin uniform W metal film 104 is deposited onto the high-k film 102 from thermal decomposition of W(CO)₆; during time period Tᵢ, the process chamber is purged of excess W(CO)₆ and reaction by-products, e.g., CO; during time period Tₛ, the W metal film 104 that was deposited during time period T_{w} is exposed to saturation dose of SiH₄ gas to form the WSiₓ film 106a in a self-limiting process; and during time period T_{f}, the process chamber is purged of the SiH₄ gas and any by-products. The deposition cycle T_{c} can be repeated a predetermined number of times to form WSiₓ gate electrode film with a desired total thickness.

FIG. 1C shows a WSiₓ film 106a formed on the high-k film 102 using one deposition cycle T_{c}. The deposition cycle T_{c} may be repeated any number of times to form a WSiₓ gate electrode film 106 with a total thickness between 1 nm and 20 nm, or between 2.5 nm and 10 nm, on the high-k film 102. FIG. 1D shows a WSiₓ gate electrode film 106 containing three WSiₓ films, i.e., WSiₓ films 106a, 106b, and 106c, formed on the high-k film 102, but embodiments of the invention contemplate the formation of a WSiₓ gate electrode film 106 containing any number of WSiₓ films on the high-k film 102.

The within-wafer (WiW) thickness uniformity of the WSiₓ films 106a, 106b, 106c, etc, and the WSiₓ gate electrode film 106 is limited by the within-wafer (WiW) thickness uniformity of the W metal film 104 deposited in each deposition cycle T_{c}. Suitable process conditions that enable deposition of a uniform W metal film 104 with a thickness between 0.1 nm and 2 nm include gas pressures between 1 mTorr and less than 500 mTorr, or between 25 mTorr and 250 mTorr and substrate temperatures between 450° C. and 550° C., or between 480° C. and 520° C. According to one embodiment of the invention, the gas pressure can be between 200 mTorr and 250 mTorr, for example about 220 mTorr and the substrate temperature can be between 450° C. and 550° C., for example 500° C. Analysis of W metal films 104 deposited at different gas pressures showed reduced C and O film impurities at gas pressures below 500 mTorr, and a minimum in WiW W metal film resistivity was observed at gas pressure of about 220 mTorr due to increased thickness uniformity of the W film. For comparison, O film impurities as high as about 30% were observed for gas pressures of 1 Torr during deposition of a W metal film 104.

According to embodiments of the invention, the gas pressure in the process chamber during time period Tᵢ, time period T_{f}, or exposure to the second process gas in time period Tₛ, or two or more thereof, can be greater or equal to the gas pressure during the first process gas exposure in time period T_{w}. In one example, the gas pressure in the process chamber during time period Tᵢ, time period T_{f}, or exposure to the second process gas in time period Tₛ, or two or more thereof, can be less than 2 Torr, for example 1 Torr, 500 mTorr, or about 220 mTorr. In one example, the gas pressure in the process chamber during time periods T_{w} and T_{f} can be similar or the same, for example about 220 mTorr, and the gas pressure in the process chamber during time periods Tᵢ and T_{w} can be similar or the same, for example about 500 mTorr.

Furthermore, the inventors have realized that substrate temperatures below 450° C. result in deposition of a W metal film 104 with too high C and O film impurities for subsequent WSiₓ gate electrode formation. This is thought to be due to incomplete dissociation of W(CO)₆. Furthermore, substrate temperatures above 550° C. result in formation of films containing tungsten carbide (WCₓ). As a result, according to embodiments of the invention, substrate temperatures between 450° C. and 550° C. enable deposition of a W metal film 104 with low C and O film impurities that is suitable for subsequent Si incorporation to form a WSiₓ gate electrode film 106.

In addition to substrate temperature and gas pressures, other adjustable process parameters include the lengths of time periods T_{w}, Tᵢ, Tₛ, and T_{f}, and any dilutions of the W(CO)₆ vapor and the SiH₄ gas. The length of each period T_{w}, Tᵢ, Tₛ, and T_{f}, can be independently varied to optimize the properties of the W metal film 104 and the WSiₓ gate electrode film 106. The length of each time period T_{w}, Tᵢ, Tₛ, and T_{f} can be the same in each deposition cycle, or alternatively, the length of each time period can vary in different deposition cycles. A length of time period T_{w} can be between about 1 sec and about 500 sec, for example between 3 sec and 11 sec. A length of time period Tₛ can be between about 1 sec and about 120 sec, for example 12 sec. A length of time periods Tᵢ and T_{f} can be less than about 120 sec, for example 12 sec.

According to one embodiment of the invention, during time period Tᵢ the process chamber may be purged by an inert purge gas, SiH₄ gas, and optionally a dilution gas. Thus, SiH₄ gas may be flowed into the process chamber and exposed to the W metal film 104 during both time periods Tᵢ and Tₛ.

### EXAMPLE 1

A WSiₓ gate electrode film 106 with a Si/W atomic ratio of 0.76 was formed on a high-k film 102 by sequential flow deposition using a first process gas containing W(CO)₆ vapor and Ar gas, a second process gas containing undiluted SiH₄ gas, continuous flow of Ar purge gas, and substrate temperature of 500° C. A 2 nm thick W metal film 104 was deposited in each deposition cycle using T_{w}=11 sec, and a gas pressure of 220 mTorr in the process chamber during time periods T_{w} and T_{f}. The length of each time period Tₛ, Tᵢ, and T_{f} was 12 sec and the gas pressure was maintained at 500 mTorr during time periods Tᵢ and Tₛ. During time period Tᵢ, the W metal film 104 was exposed to Ar purge gas and SiH₄ gas and during time period Tᵢ, the WSiₓ film was exposed to Ar purge gas only. The O film impurity in the WSiₓ gate electrode film 106 was 16.7%.

### EXAMPLE 2

A WSiₓ gate electrode film 106 with a Si/W atomic ratio of 2.6 was formed on a high-k film 102 by sequential flow deposition using a first process gas containing W(CO)₆ vapor and Ar gas, a second process gas containing undiluted SiH₄ gas, continuous flow of Ar purge gas, and substrate temperature of 500° C. A 1 nm thick W metal film 104 was deposited in each deposition cycle using T_{w}=5 sec, and a gas pressure of 220 mTorr in the process chamber during time periods T_{w} and T_{f}. The length of each time period Tₛ, Tᵢ, and T_{f} was 12 sec and the gas pressure was maintained at 500 mTorr during time periods Tᵢ and Tₛ. During time period Tᵢ, the W metal film 104 was exposed to Ar purge gas and SiH₄ gas and during time period Tᵢ, the WSiₓ film was exposed to Ar purge gas only. The O film impurity in the WSiₓ gate electrode film 106 was 2.9%.

### EXAMPLE 3

A WSiₓ gate electrode film 106 with a Si/W atomic ratio estimated at 3.5-4 was formed on a high-k film 102 by sequential flow deposition using a first process gas containing W(CO)₆ vapor and Ar gas, a second process gas containing undiluted SiH₄ gas, continuous flow of Ar purge gas, and substrate temperature of 500° C. A 0.5 nm thick W metal film 104 was deposited in each deposition cycle using T_{w}=3 sec, and a gas pressure of 220 mTorr in the process chamber during time periods T_{w} and T_{f}. The length of each time period Tₛ, Tᵢ, and T_{f} was 12 sec and the gas pressure was maintained at 500 mTorr during time periods Tᵢ and Tₛ. During time period Tᵢ, the W metal film 104 was exposed to Ar purge gas and SiH₄ gas and during time period Tᵢ, the WSiₓ film was exposed to Ar purge gas only. The O film impurity in the WSiₓ gate electrode film 106 was <2.9%.

As shown in Examples 1-3 above, the Si/W atomic ratio of a WSiₓ gate electrode film 106 was varied from about 0.76 to about 3.5-4 by controlling the thickness of the W metal film 104 deposited in each deposition cycle prior to the SiH₄ exposure. In particular, the thickness of the W metal film 104 in Examples 1-3 above was varied from 0.5 nm to 2 nm. The current inventors have realized that the thickness of the W metal film 104 can range from 0.1 nm to less than 2 nm for tunable work function control of the WSiₓ gate electrode film 106 and a semiconductor device containing the WSiₓ gate electrode film 106. A thickness of less than 2 nm is estimated to be an upper thickness limit that is suitable for high-volume semiconductor manufacturing in view of O film impurities in the WSiₓ gate electrode film 106. In another example, the thickness can be between 0.1 nm and less than 0.5 nm, for example about 0.2 nm. In other examples, the Si/W atomic ratio of a WSiₓ gate electrode film 106 may be varied from greater than 2 to about 3.5-4, or from greater than 3 to about 3.5-4, by choosing an appropriate thickness of the W metal film 104.

As shown in Examples 1-3 above, the O film impurity in the WSiₓ gate electrode film 106 was 16.7% using a 2 nm W metal film 104, 2.9% when using a 1 nm thick W metal film 104, and <2.9% when using a 0.5 nm thick W metal film 104. Clearly, the O film impurity is greatly reduced as the W metal film 104 gets thinner. Further analysis of the film structures showed an increase of about 0.5 nm in the equivalent oxide thickness (EOT) in Example 1 due to an increase in interface layer thickness between the high-k film 102 and the substrate 100. In the semiconductor industry, requirements for devices having linewidths of 45 nm and 32 nm include EOTs of about 1.2 nm and 1.0 nm, respectively. As those skilled in the art will readily realize, an increase of about 0.5 nm in the EOT during processing, about half of the total EOT required for these gate stacks, is not acceptable for manufacturing of advanced devices. Unlike the WSiₓ gate electrode film 106 in Example 1, the WSiₓ gate electrode film 106 in Examples 2-3 had acceptable O film impurities. Thus according to embodiments of the invention, the O film impurity can be less than 16.7%, for example, 2.9%, or less than 2.9%, and the thickness of the W metal film 104 can range from 0.1 nm to less than 2 nm.

The high Si/W atomic ratios for Si-incorporation into thin W metal films 104 may be explained by the self-limiting reaction of the SiH₄ gas with the W metal films 104. Since diffusion of a Si species through an existing WSiₓ surface portion of the W metal film 104 and subsequent reaction of the Si species with an unreacted portion of the W metal film 104 is required, the rate of Si incorporation decreases as the thickness of the WSiₓ surface portion increases.

Importantly, the Si/W atomic ratio of the WSiₓ gate electrode film 106 may be easily controlled over a large range of Si/W atomic ratios while achieving excellent WSiₓ film thickness and composition uniformity across large substrates. This allows semiconductor device manufacturers to incorporate WSiₓ gate electrode films with tunable Si/W atomic ratios and work functions into gate stacks for advanced transistors. In other words, a thickness of the W metal film may be selected that results in a predetermined Si/W atomic ratio and work function of the WSiₓ gate electrode film.

In an alternative embodiment of the invention, the purge gas can be sequentially flowed into the process chamber when one of the W(CO)₆ vapor and the SiH₄ gas are not flowing, for example during time periods Tᵢ and T_{f}. In an alternative embodiment of the invention, a purge gas can be omitted from the sequential flow deposition process.

FIG. 1E schematically shows a cross-sectional view of a partially manufactured gate stack according to an embodiment of the invention. In the schematic cross-sectional view, source and drain regions are not shown. The gate stack contains a substrate 100, a patterned high-k film 102′ that serves as a gate dielectric, and a patterned WSiₓ gate electrode film 106′. Although not shown in FIG. 1E, the gate stack may further contain an interface layer between the patterned high-k film 102′ and a patterned WSiₓ gate electrode film 106′. The partially manufactured gate stack shown in FIG. 1E may be formed from the film structure shown in FIG. 1D using lithographical patterning and etching methods well known to those skilled in the art.

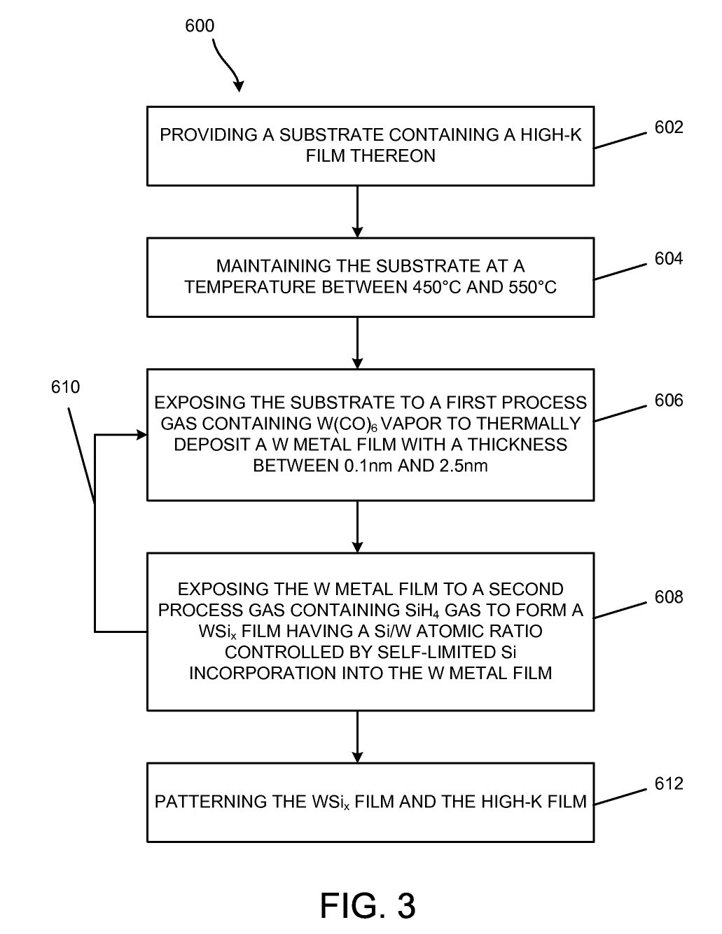

FIG. 3 is a process flow diagram 600 for forming a gate stack according to an embodiment of the invention. At 602, a substrate 100 containing a high-k film 102 formed thereon is provided in a process chamber, and at 604, the substrate 100 is heated and maintained at a temperature between 450° C. and 550° C. At 606, the substrate 100 is exposed to a first process gas containing W(CO)₆ vapor to thermally deposit a W metal film 104 with a thickness between 0.1 nm and 2.5 nm on the high-k film 102. At 608, the W metal film104 is exposed to a second process gas containing SiH₄ to form a WSiₓ film having a Si/W atomic ratio controlled by self-limited Si incorporation into the W metal film 104. Steps 606 and 608 may be repeated any number of times as indicated by process flow arrow 610 until a WSiₓ gate electrode film 106 with a desired thickness and Si/W atomic ratio has been formed on the high-k film 102. At 612, the WSiₓ gate electrode film 106 and the high-film 102 are patterned to form a gate stack containing a patterned WSiₓ gate electrode film 106′ and a patterned high-k film 102′.

FIG. 4 depicts a schematic view of a processing system for forming a WSiₓ gate electrode film according to an embodiment of the invention. The processing system 200 contains a process chamber 1 that contains an upper chamber section 1a, a lower chamber section 1b, and an exhaust chamber 23. A circular opening 22 is formed in the middle of lower chamber section 1b, where lower bottom section 1b connects to exhaust chamber 23.

Provided inside process chamber 1 is a substrate holder 2 for horizontally holding a substrate (wafer) 100 to be processed. The substrate holder 2 is supported by a cylindrical support member 3, which extends upward from the center of the lower part of exhaust chamber 23. A guide ring 4 for positioning the substrate 100 on the substrate holder 2 is provided on the edge of substrate holder 2. Furthermore, the substrate holder 2 contains a heater 5 that is controlled by power source 6, and is used for heating the substrate 100. The heater 5 can be a resistive heater. Alternately, the heater 5 may be a lamp heater.

During processing, the heated substrate 100 thermally decomposes a W(CO)₆ precursor and enables deposition of a W metal film on the substrate 100. The substrate holder 2 is heated to a pre-determined temperature that is suitable for depositing a desired thickness of the W metal film onto the substrate 100. A heater (not shown) is embedded in the walls of process chamber 1 to heat the chamber walls to a pre-determined temperature. The heater can maintain the temperature of the walls of process chamber 1 from about 40° C. to about 80° C.

A showerhead 10 is located in the upper chamber section 1a of process chamber 1. Showerhead plate 10a at the bottom of showerhead 10 contains multiple gas delivery holes 10b for delivering a first process gas comprising the W(CO)₆ vapor into a processing zone 60 located above the substrate 100. The processing zone 60 is a volume defined by the substrate diameter and by the gap between the substrate 100 and the showerhead 10.

An opening 10c is provided in upper chamber section 1a for introducing a process gas from gas line 12 into a gas distribution compartment 10d. Concentric coolant flow channels 10e are provided for controlling the temperature of the showerhead 10 and thereby preventing the decomposition of the W(CO)₆ vapor inside the showerhead 10. A coolant fluid such as water can be supplied to the coolant flow channels 10e from a coolant fluid source 10f for controlling the temperature of showerhead 10 from about 20° C. to about 100° C.

The gas line 12 connects the precursor delivery system 300 to process chamber 1. A precursor container 13 contains a solid W(CO)₆ precursor 55, and a precursor heater 13a is provided for heating the precursor container 13 to maintain the W(CO)₆ precursor 55 at a temperature that produces a desired vapor pressure of the W(CO)₆ precursor. The W(CO)₆ precursor 55 has a relatively high vapor pressure, Pᵥₐₚ˜1 Torr at 65° C. Therefore, only moderate heating of the precursor container 13 and the precursor gas delivery lines (e.g., gas line 12) is required for delivering the W(CO)₆ vapor to the process chamber 1. Furthermore, the W(CO)₆ vapor does not thermally decompose at temperatures below about 200° C. This can significantly reduce decomposition of the W(CO)₆ vapor due to interactions with heated chamber walls and gas phase reactions.

In one embodiment, W(CO)₆ vapor can be delivered to the process chamber 1 without the use of a carrier gas or, alternatively, a carrier gas can be used to enhance the delivery of the precursor vapor to the process chamber 1. Gas line 14 can provide a carrier gas from gas source 15 to the precursor container 13, and a mass flow controller (MFC) 16 can be used to control the carrier gas flow. When a carrier gas is used, it may be introduced into the lower part of precursor container 13 so as to percolated through the solid W(CO)₆ precursor 55. Alternatively, the carrier gas may be introduced into the precursor container 13 and distributed across the top of the solid W(CO)₆ precursor 55. A sensor 45 is provided for measuring the total gas flow from the precursor container 13. The sensor 45 can, for example, contain a MFC, and the amount of W(CO)₆ precursor delivered to the process chamber 1, can be determined using sensor 45 and mass flow controller (MFC) 16. Alternatively, the sensor 45 can contain a light absorption sensor to measure the concentration of the W(CO)₆ vapor in the flow of the first process gas to the process chamber 1.

A bypass line 41 is located downstream from sensor 45 and connects gas line 12 to exhaust line 24. Bypass line 41 provided for evacuating gas line 12 and for stabilizing the supply of the W(CO)₆ vapor to the process chamber 1. In addition, a valve 42, located downstream from the branching of gas line 12, is provided on bypass line 41

Heaters (not shown) are provided to independently heat gas lines 12,14, and 41, where the temperatures of the gas lines can be controlled to avoid condensation of the W(CO)₆ vapor in the gas lines. The temperature of the gas lines can be controlled from about 20° C. to about 100° C., or from about 25° C. to about 60° C.

Dilution gases can be supplied from gas source 19 to gas line 12 using gas line 18. The dilution gases can be used to dilute the process gas or to adjust the process gas partial pressure(s). Gas line 18 contains a MFC 20 and valves 21. MFCs 16 and 20, and valves 17, 21, and 42 are controlled by controller 40, which controls the supply, shutoff, and the flow of a carrier gas, the W(CO)₆ vapor, and a dilution gas. Sensor 45 is also connected to controller 40 and, based on output of the sensor 45, controller 40 controls the carrier gas flow through mass flow controller 16 to obtain the desired W(CO)₆ vapor flow to the process chamber 1. SiH₄ gas can be supplied from gas source 61 to the process chamber 1 using gas line 64, MFC 63, and valves 62. A purge gas can be supplied from gas source 65 to process chamber 1 using gas line 68, MFC 67, and valves 66. Controller 40 controls the supply, shutoff, and the flow of the dilution gas and the purge gas.

Exhaust line 24 connects exhaust chamber 23 to vacuum pumping system 400. Vacuum pump 25 is used to evacuate process chamber 1 to the desired degree of vacuum and to remove gaseous species from the process chamber 1 during processing. An automatic pressure controller (APC) 59 and a trap 57 can be used in series with the vacuum pump 25. The vacuum pump 25 can include a turbo-molecular pump (TMP) capable of a pumping seed up to about 5000 liters per second (and greater). Alternatively, the vacuum pump 25 can include a dry pump. During processing, the process gas can be introduced into the process chamber 1 and the chamber pressure adjusted by the APC 59. The APC 59 can contain a butterfly-type valve or a gate valve. The trap 57 can collect unreacted W(CO)₆ vapor and by-products from the process chamber 1.

In the process chamber 1, three substrate lift pins 26 (only two are shown) are provided for holding, raising, and lowering the substrate 100. The substrate lift pins 26 are affixed to plate 27, and can be lowered to below to the upper surface of substrate holder 2. A drive mechanism 28 utilizing, for example, an air cylinder, provides means for raising and lowering the plate 27. A substrate 100 can be transferred in and out of process chamber 1 through gate valve 30 and chamber feed-through passage 29 via a robotic transfer system (not shown) and received by the substrate lift pins. Once the substrate 100 is received from the transfer system, it is lowered to the upper surface of the substrate holder 2 by lowering the substrate lift pins 26.

A processing system controller 500 includes a microprocessor, a memory, and a digital I/O port capable of generating control voltages sufficient to communicate and activate inputs of the processing system 200 as well as monitor outputs from the processing system 200. Moreover, the processing system controller 500 is coupled to and exchanges information with process chamber 1, precursor delivery system 300 that includes controller 40 and precursor heater 13a, vacuum pumping system 400, power source 6, and coolant fluid source 10f. In the vacuum pumping system 400, the processing system controller 500 is coupled to and exchanges information with the APC 59 for controlling the pressure in the process chamber 1. A program stored in the memory is utilized to control the aforementioned components of a processing system 200 according to a stored process recipe.

A plurality of embodiments for sequential flow deposition of conformal WSiₓ gate electrode films has been described. The embodiments use alternating exposures of W(CO)₆ vapor and SiH₄ gas for depositing WSiₓ films with tunable Si/W atomic ratios and work functions. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a first film “on” a second film is directly on and in immediate contact with the second film unless such is specifically stated; there may be a third film or other structure between the first film and the second film on the first film.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a gate stack, comprising:
providing a substrate in a process chamber, the substrate containing a high-k film thereon;
maintaining the substrate at a temperature between 450° C. and 550° C.;
performing a plurality of sequential flow deposition cycles to form a tungsten silicide (WSiₓ) gate electrode film on the high-k film, each cycle comprising:
exposing the substrate to a first process gas containing tungsten hexacarbonyl (W(CO)₆) vapor to thermally deposit a tungsten (W) metal film with a thickness between 0.1 nm and less than 2 nm, and
exposing the W metal film to a second process gas comprising silane (SiH₄) to form a WSiₓ film having a silicon/tungsten (Si/W) atomic ratio controlled by self-limited Si incorporation into the W metal film; and
patterning the WSiₓ gate electrode film and the high-k film.

2. The method of claim 1, wherein the thickness of the W metal film is between 0.1 nm and less than 0.5 nm.

3. The method of claim 1, wherein the substrate is maintained at a temperature between 480° C. and 520° C.

4. The method of claim 1, wherein a thickness of the WSiₓ gate electrode film is between 1 nm and 20 nm.

5. The method of claim 1, wherein a thickness of the WSiₓ gate electrode film is between 2.5 nm and 10 nm.

6. The method of claim 1, wherein gas pressure in the process chamber is between 1 mTorr and 500 mTorr during the first process gas exposure.

7. The method of claim 6, wherein gas pressure in the process chamber during the second process gas exposure is greater or equal to the gas pressure during the first process gas exposure.

8. The method of claim 7, wherein gas pressure in the process chamber during the second process gas exposure is less than 2 Torr.

9. The method of claim 1, wherein gas pressure in the process chamber is between 200 mTorr and 250 mTorr during the first process gas exposure.

10. The method of claim 1, wherein the first process gas consists of W(CO)₆ vapor and an inert gas selected from a noble gas or N₂ gas.

11. The method of claim 1, wherein the second process gas further comprises an inert gas selected from a noble gas or N₂ gas.

12. The method of claim 1, wherein the WSiₓ gate electrode film has the Si/W atomic ratio between greater than 0.76 and 3.5-4.

13. The method of claim 1, wherein each deposition cycle further comprises:
continuously flowing a purge gas in the process chamber.

14. The method of claim 1, wherein the exposure to the second process gas incorporates Si into at least an exposed surface portion of the W metal film.

15. The method of claim 1, wherein an oxygen film impurity in the WSiₓ gate electrode film is lower than 16.7%.

16. The method of claim 1, wherein an oxygen film impurity in the WSiₓ gate electrode film is 2.9% or lower.

17. The method of claim 1, further comprising:
selecting the thickness of the W metal film that results in a predetermined Si/W atomic ratio and work function of the WSiₓ gate electrode film, wherein exposing the substrate to the first a process gas comprises depositing the W film with the selected thickness.

18. A method of forming a gate stack, comprising:
providing a substrate in a process chamber, the substrate containing a high-k film thereon;
continuously flowing a purge gas in the process chamber;
maintaining the substrate at a temperature between 450° C. and 550° C.;
performing a plurality of sequential flow deposition cycles to form a tungsten silicide (WSiₓ) gate electrode film having a silicon/tungsten (Si/W) atomic ratio between greater than 0.76 and 3.5-4 and having a thickness between 2.5 nm and 10 nm on the high-k film, each deposition cycle comprising:
exposing the substrate to a first process gas containing tungsten hexacarbonyl (W(CO)₆) vapor and argon (Ar) gas at a gas pressure between 1 mTorr and 500 mTorr to thermally deposit a tungsten (W) metal film with a thickness between 0.1 nm and less than 2 nm, and
exposing the W metal film to a second process gas comprising SiH₄ to form a WSiₓ film, wherein the Si/W atomic ratio is controlled by self-limited Si incorporation into the W metal film; and
patterning the WSiₓ gate electrode film and the high-k film.

19. The method of claim 18, wherein the second process gas further comprises an inert gas selected from a noble gas or N₂ gas.

20. The method of claim 18, further comprising:
selecting the thickness of the W metal film that results in a predetermined Si/W atomic ratio and work function of the WSiₓ gate electrode film, wherein exposing the substrate to the first a process gas comprises depositing the W film with the selected thickness.
